(19) United States
(12) Patent Application Publication
(10) Pub. No.: US 2022/0318471 A1
(43) Pub. Date: Oct. 6, 2022

(54) AUTONOMOUS CONTROL BOARD

(71) Applicant: YAMAHA HATSUDOKI KABUSHIKI KAISHA, Iwata-shi (JP)

(72) Inventors: Yuji HIRAMATSU, Shizuoka (JP); Yu KINOSHITA, Shizuoka (JP); Hirofumi NONOGUCHI, Shizuoka (JP)

(21) Appl. No.: 17/842,685

(22) Filed: Jun. 16, 2022

Related U.S. Application Data
(63) Continuation-in-part of application No. PCT/JP2020/047153, filed on Dec. 17, 2020.

(30) Foreign Application Priority Data
Dec. 17, 2019 (JP) PCT/JP2019/049329

(51) Int. Cl. G06F 30/343; G05B 13/02

(52) U.S. Cl. CPC G06F 30/343; G05B 13/026

(57) ABSTRACT

An external control FPGA device includes a command receiving terminal configured to receive command data, a control outputting terminal configured to output a functioning control signal, and a plurality of FPGA connection terminals, and a data processing FPGA device that transmits a control command from an external command data receiver to a control signal outputter. The data processing FPGA device is connected to one of the plurality of FPGA connection terminals through a data processing line that is independent of a command transmission pathway including an external command data receiver, a command data line, the external control FPGA device, a functioning control signal line and the control signal outputter. The data processing FPGA device inputs data that is to be processed from the external control FPGA device through the data processing line, and outputs the processed data to the external control FPGA device.

### CROSS-REFERENCE TO RELATED APPLICATIONS

This is a continuation-in-part application of International Application PCT/JP2020/047153, filed on Dec. 17, 2020, which claims priority from International Application PCT/JP2019/049329, filed on Dec. 17, 2019. The contents of the applications are incorporated herein by reference.

### TECHNICAL FIELD

The present teaching relates to an autonomous control board for an autonomous functioning apparatus.

### BACKGROUND ART

For example, Patent Literature 1 discloses a control device for an autonomous vehicle. The autonomous vehicle in PTL 1 is either an electric vehicle or a hybrid vehicle.

In PTL 1, a controller, which corresponds to a control device, mainly consists of a micro-computer. The controller is configured to perform a calculation using inputted data, prestored data, and a program, and to output a calculated result as a control command signal. The vehicle is capable of so-called autonomous travelling; the vehicle can travel without human operation, through the autonomous control of each of; motor, braking device, and/or steering device. During autonomous travelling as described above, such each of the motor, the braking device, the steering device or the like are controlled by the controller.

### CITATION LIST

### Patent Document

[Patent Document 1] Japanese Unexamined Patent Publication No.2019-187130

### SUMMARY OF INVENTION

### Technical Problem

It is desired to provide a highly scalable and highly versatile autonomous control board for controlling an autonomous functioning apparatus such as the automobile as disclosed in PTL 1.

It is an objective of the present teaching to provide a highly scalable and highly versatile autonomous control board for use in an autonomous functioning apparatus.

### Solution to the Problem

The present inventors have studied a hardware configuration of an autonomous control board.

For example, the control device as described in PTL 1 needs a hardware configuration capable of executing a program for autonomously travelling an automobile. Accordingly, the hardware configuration in PTL 1 is suitable for controlling an automobile.

However, an autonomous functioning apparatus generally involves a wider variety of and a broader scale of processing compared to an automobile. Consequently, when autonomous functioning apparatuses other than automobiles are to be controlled, it is desirable that types and scales of processing can be changed depending on the control object. Examples of the autonomous functioning apparatus include a low-speed vehicle and a transport robot. In addition, types of functioning mechanism, required response speed, and external environment to be recognized are dependent on the types of control object. When these functions are controlled, a hardware configuration of the control device in PTL 1 may become complex and redundant.

The present inventors have studied a configuration of an autonomous control board that can be applied both to the autonomous functioning apparatus having a simple configuration and the autonomous functioning apparatus having a complex configuration.

One example of a simple configuration may be set to a robot arm that functions based on data from an external environment sensor such as one distance sensor. One example of a complex configuration may be set to an automobile that functions based on a large number of external environment sensors such as a large number of cameras.

The autonomous control board for these autonomous functioning apparatuses needs a hardware configuration with high scalability for the scale of control processing and with high versatility in response to the difference in the amount or the type of input data.

For example, in order to control the functioning of the object in response to a command from outside of the autonomous functioning apparatus while performing high-speed processing of huge amounts of information such as image recognition, a field-programmable gate array (FPGA) device having a reconfigurable logic circuit may be employed. For example, Japanese Unexamined Patent Publication No.2019-041324 discloses a system including an FPGA device.

As the functions required for the autonomous functioning apparatus become more advanced, the amounts of commands may be increased or contents of commands may become more abstract, and only a single FPGA device may fail to process such commands. One solution to this problem may be employing a plurality of FPGA devices.

FIG. 5 is a block diagram showing a conventional solution, in which a plurality of FPGA devices is employed in response to processing that cannot be performed by a single FPGA device.

Part (a) in FIG. 5 shows an autonomous functioning apparatus E having a single FPGA device F1. The FPGA device F1 receives command data from outside of the autonomous functioning apparatus. The FPGA device F1 performs the process P1. In addition, the FPGA device F1 outputs a signal that controls the control object J. In some cases, the FPGA device F1 may receive, from the control object J, a signal representing a state of the control object (not shown).

For example, as apparatuses become more advanced, a command from outside of the autonomous functioning apparatus may be changed from a specific command to a highly abstract one, where one example of the specific command is to respond to the start and stop of one functioning of the control object J and one example of the highly abstract command is to respond to the start and stop of a series of functioning including a plurality of functioning. As described above, as commands from outside of the autonomous functioning apparatus become more abstract, the amounts of data processing by the FPGA device F1 may be increased. One solution to such increased amount of data processing may be increasing the number of FPGA device. Specifically, there may be a configuration such as the one shown in Part (b) in FIG. 5, where data processing is divided into upstream processing P2A and downstream processing P2B along the transmission of the command, so that upstream FPGA device F2A performs the upstream processing P2A, and downstream FPGA device F2B performs the downstream processing P2B. For example, Japanese Unexamined Patent Publication No.2001-322078 discloses a configuration in which the processing is divided into the upstream and the downstream.

However, for example, as the apparatuses become even further advanced, commands from outside of the autonomous functioning apparatus may become more abstract.

One solution to such a case may be further increasing the number of FPGA devices. For example, as shown in Part(c) in FIG. 5, the upstream FPGA device F3A, the midstream FPGA device F3B, and the downstream FPGA device F3C may respectively perform the processing P3A, P3B, and P3C.

However, in this solution, when a command from outside of the apparatus becomes more abstract, it is required to redesign the way to divide processing from the upstream to the downstream and to reconsider the circuit design, arrangement, and interconnection of the board on which the necessary number of FPGA devices are to be mounted.

The present inventors have studied the following configuration of the autonomous control board for use in the autonomous functioning apparatus.

The autonomous control board has a functioning control signal generation circuit. The functioning control signal generation circuit includes an external control FPGA device and one or more data processing FPGA devices.

The external control FPGA device includes a command receiving terminal and a control outputting terminal. The command receiving terminal is connected to the external command data receiver through the command data line. The command receiving terminal receives the command data from the command device that is off-board the autonomous functioning apparatus.

The control outputting terminal is connected to the functioning control signal generation circuit and outputs the functioning control signal for controlling the on-board controlled object.

A command transmission pathway that is configured to transmit a control command from the external command data receiver to the control signal outputter includes the external command data receiver, the command data line, the external control FPGA device, the functioning control signal line and the control signal outputter.

The data processing FPGA device has one-to-one connection to any one of a plurality of FPGA connection terminals through a data processing line that is independent of the command transmission pathway, wherein the data processing FPGA device inputs data that is to be processed from the external control FPGA device through the data processing line and outputs the processed data to the external control FPGA device.

As described above, as the autonomous functioning apparatuses become more advanced, the content of the command data received from the command device may become more abstract. For example, some commands may be completed by performing advanced processing such as the one in which the autonomous functioning apparatus travels to the destination while regulating the travelling route in accordance with the image recognition result based on the camera data after receiving command data including the destination. In such a case, when one or more data processing FPGA devices are not connected to the external environment data obtainer, and the external control FPGA device is connected to both the external command data receiver and the control signal outputter, increased processing can be responded to. This is achieved by regulating the number of data processing FPGA devices that are connected to a plurality of FPGA connection terminals without changing connections to the external command data receiver and to the control signal outputter. Furthermore, a processor provided in the external control FPGA device executes software. Accordingly, the external control FPGA device can flexibly distribute processing to the data processing FPGA devices depending on the increased or decreased amounts of external environment data outputted from the external environment sensor. Consequently, high scalability is achieved for various applications of the autonomous functioning apparatus.

As autonomous functioning apparatuses become more advanced, some types of autonomous functioning apparatuses may be provided with an external environment sensor with improved performance, and thus the amount of external environment data outputted from the external environment sensor may be different from that of the conventional sensor. In such a case, since one or more data processing FPGA devices are not connected to the external environment data obtainer and the external control FPGA device is connected to the external command data obtainer, the different amounts of data can be processed without changing the connection to the external environment data obtainer, by regulating the number of data processing FPGA devices that are connected to a plurality of FPGA connection terminals. Since both the logic circuit of the external control FPGA device and the data processing FPGA device are programmable, the logic circuit constructed in both FPGA devices can be easily changed when the application of the autonomous control board is changed. In addition, for example, in response to the additional input of data other than the external environment data, the external control FPGA device configured to execute software can flexibly distribute the processing and the data to the data processing FPGA devices.

Consequently, according to the above configuration, high versatility is achieved for the types of the on-board controlled object in the autonomous functioning apparatus.

The autonomous control board according to each aspect of the present teaching, which has been achieved based on the above understanding, has following configuration.

(1) An autonomous control board for an autonomous functioning apparatus, the autonomous functioning apparatus autonomously performing a series of functioning based on command data transmitted from a command device, the command device being on-board or off-board the autonomous functioning apparatus, the autonomous control board comprising:

an external command data receiver configured to obtain command data transmitted from the command device, the command device commanding at least an initiation of a series of functioning;

an external environment data obtainer communicatively connected to an external environment sensor, the external environment data obtainer being configured to obtain external environment data outputted from the external environment sensor, and the external environment sensor obtaining external environment information of the autonomous functioning apparatus;

a control signal outputter communicatively connected to an on-board controlled object, the control signal outputter being configured to output a functioning control signal to the on-board controlled object that is disposed outside of the autonomous control board, the on-board controlled object being on-board the autonomous functioning apparatus and being different from the command device, and the functioning control signal controlling the on-board controlled object; and,

a functioning control signal generation circuit configured to generate the functioning control signal based on the command data,

the functioning control signal generation circuit comprising:
an external control FPGA device including a first logic circuit that is programmable and a processor;
one or more data processing FPGA devices each including a second logic circuit that is programmable;

the functioning control signal generation circuit further comprising:
a command data line configured to transmit the command data from the external command data receiver to the external control FPGA device; and
a functioning control signal line configured to transmit the functioning control signal from the external control FPGA device to the control signal outputter,

characterized in that:

the external control FPGA device comprising:

a command receiving terminal connected to the external command data receiver through the command data line, the command receiving terminal being configured to receive the command data from the command device that is off-board the autonomous functioning apparatus;

a control outputting terminal connected to the control signal outputter, the control outputting terminal being configured to output the functioning control signal for controlling the on-board controlled object; and

a plurality of FPGA connection terminals configured to communicatively connect to the one or more data processing FPGA devices,

the autonomous control board including a command transmission pathway, the command transmission pathway being configured to transmit a control command between the external command data receiver and the control signal outputter, the control command being either the command data or the functioning control signal, the command transmission pathway including the external command data receiver, the command data line, the external control FPGA device, the functioning control signal line and the control signal outputter,

the data processing FPGA device having one-to-one connection to any one of a plurality of FPGA connection terminals through a data processing line that is independent of the command transmission pathway, the data processing FPGA device inputting data that is to be processed from the external control FPGA device through the data processing line and outputting the processed data to the external control FPGA device.

The external control FPGA device in the configuration described above includes the command receiving terminal and the control outputting terminal. The command receiving terminal is connected to the external command data receiver through the command data line. The command receiving terminal receives the command data from the command device that is off-board the autonomous functioning apparatus.

The control outputting terminal is connected to the functioning control signal generation circuit and outputs the functioning control signal for controlling the on-board controlled object.

The autonomous control board includes a command transmission pathway. The command transmission pathway is configured to transmit a control command between the external command data receiver and the control signal outputter. The control command is either the command data or the functioning control signal.

The data processing FPGA device has one-to-one connection to any one of a plurality of FPGA connection terminals through a data processing line that is independent of the command transmission pathway. The data processing FPGA device inputs data that is to be processed from the external control FPGA device through the data processing line and outputs the processed data to the external control FPGA device.

As the autonomous functioning apparatuses become more advanced, the command data received from the command device may become more abstract. For example, commands for travelling may be performed while performing advanced processing such as the one in which the autonomous functioning apparatus travels to the destination while regulating the travelling route in accordance with the image recognition result based on the camera data after receiving command data including the destination. In such a case, since one or more data processing FPGA devices are not connected to the external command data receiver, and the external control FPGA device is connected to both the external command data receiver and the control signal outputter, increased processing can be responded to. This is achieved by regulating the number of data processing FPGA devices that are connected to a plurality of FPGA connection terminals without changing connections to the external command data receiver and to the control signal outputter. A processor provided in the external control FPGA device executes software. Accordingly, the external control FPGA device can flexibly distribute processing to the data processing FPGA devices depending on the increased or decreased amounts of external environment data outputted from the external environment sensor in association with command data. Consequently, high scalability is achieved for various applications of the autonomous functioning apparatus.

As autonomous functioning apparatuses become more advanced, the performance of an external environment sensor may be changed depending on types of autonomous functioning apparatuses, and thus the amount of external environment data outputted from the external environment sensor may be different from that of the conventional sensor. In such a case, one or more data processing FPGA devices are not directly connected to the external environment data obtainer and the external control FPGA device is connected to the external environment data receiver. Thus, the different amounts of data can be processed without changing the connection to the external environment data obtainer, by regulating the number of data processing FPGA devices for processing data. Since both the logic circuit of the external control FPGA device and the data processing FPGA device are programmable, the logic circuit constructed in both FPGA devices can be easily changed when the application of the autonomous control board is changed. In addition, for example, in response to the additional input of data other than the external environment data, the external control FPGA device configured to execute software can flexibly distribute the processing and the data to the data processing FPGA devices.

Consequently, according to the above configuration, high versatility is achieved for the types of the on-board controlled object in the autonomous functioning apparatus.

(2) The autonomous control board according to (1),

the external environment sensor being a camera that captures an external environment of the autonomous functioning apparatus to output image data corresponding to the external environment data,

the external environment data obtainer obtaining the image data outputted from the camera.

Image data outputted from a camera generally has a large amount of data. The autonomous control board in the above configuration can control the on-board controlled object provided in the autonomous functioning apparatus based on image data as external environment data outputted from the camera. The autonomous control board in the above configuration has high scalability, and therefore can process a large amount of data such as image data.

(3) The autonomous control board according to (1) or (2),

being constituted of a single printed wiring board on which a command data line and a functioning control signal line are formed, the external control FPGA device, the one or more data processing FPGA devices, an external command data receiver and a control signal outputter being mounted on the single printed wiring board.

According to the above configuration, the external control FPGA device, the one or more data processing FPGA devices, an external command data receiver and a control signal outputter are mounted on the single printed wiring board. Accordingly, high scalability can be achieved, without, for example, changing the arrangement space in the autonomous functioning apparatus for the printed wiring board in response to the change of the processing contents.

(4) The autonomous control board according to (3),

the single printed wiring board having a plurality of data processing device mount areas that receives a plurality of data processing lines extending from the external control FPGA device and on which each of the one or more data processing FPGA devices is mountable,

the one or more data processing FPGA devices being mounted on a part of or all of the plurality of data processing device mount areas.

According to the above configuration, for example, when a single data processing FPGA is mounted on one of the plurality of data processing device mount areas, more data can be processed by the addition of the data processing FPGA to the empty data processing device mount area. On the other hand, for example, when a plurality of data processing FPGAs is mounted on all of the plurality of data processing device mount areas, less data can be processed by the removal of the mounted data processing FPGA. In this way, high scalability can be achieved by regulating the number of data processing FPGA on the plurality of data processing device mount areas.

(5) The autonomous control board according to any one of (1) to (4), further comprising:

a non-volatile second memory configured to store a second configuration data that represents at least a part of a circuit constructed by the second logic circuit of one of the data processing FPGA devices, the non-volatile second memory being electrically connected to one of the data processing FPGA devices; and

a non-volatile first memory configured to store a first configuration data that represents a circuit constructed by the first logic circuit of the external control FPGA device, the non-volatile first memory being electrically connected to one of the external control FPGA devices, the non-volatile first memory having a capacity equal to or more than the capacity of any of the second memories.

According to the above configuration, the first memory connected to the external control FPGA device can store configuration data larger than the second memory connected to one of the data processing FPGA devices. In this case, configuration data of the circuit for processing data in the data processing FPGA device can be stored in the first memory, and minimal configuration data for constructing the circuit in the data processing FPGA device can be stored in the second memory. For example, configuration data that constructs an initialization circuit in the data processing FPGA device can be stored in the second memory. The initialization circuit that is constructed in the data processing FPGA device transfers configuration data of the circuit for processing data on an image from the first memory through the external control FPGA device. The initialization circuit constructs a circuit for processing data on an image in the data processing FPGA device based on the transferred configuration data.

In this case, at least configuration data of the initialization circuit may be stored in the second memory. Consequently, for example, when the number of the data processing FPGA device is increased depending on the application and the scale of the autonomous control board, contents of the second memory that is connected to each data processing FPGA device are easy to be shared. Therefore, the number of the data processing FPGA device is easily increased or decreased. Thus, higher scalability and higher versatility can be achieved.

(6) The autonomous control board according to any one of (1) to (5),

each of the plurality of the FPGA connection terminals of the external control FPGA device being a high-speed transfer terminal having a maximum data transfer speed higher than the maximum data transfer speed of the external environment data.

According to the above configuration, the external control FPGA device can transfer data to each data processing FPGA device at a speed higher than the maximum data transfer speed of the external environment data. This enables, for example, to transmit the external environment data to each data processing FPGA device and to cause each data processing FPGA device to perform processing for generating a functioning control signal.

(7) The autonomous control board according to any one of (1) to (6), each of the one or more data processing FPGA devices having a processor.

The data processing FPGA device having a processor can perform processing more flexibly, and therefore the data processing FPGA device can perform wider variety of processing. Consequently, according to the above configuration, high versatility is achieved for the types of the on-board controlled object in the autonomous functioning apparatus.

(8) The autonomous control board according to any one of (1) to (7),

the FPGA connection terminal performing serial communication.

According to the above configuration, the number of FPGA connection terminal used for connecting the external control FPGA device with the data processing FPGA device is smaller than in the case of, for example, other than serial communication. Consequently, more data processing FPGA devices can be connected to the external control FPGA device. Thus, the number of data processing FPGA devices can be increased or decreased more easily. Therefore, higher scalability can be achieved.

(9) The autonomous control board according to any one of (1) to (8),

further comprising a debug connector connected to each of the one or more data processing FPGA devices, the debug connector being removably connectable to a communication device that is communicable with the data processing FPGA device.

According to the above configuration, for example during the maintenance of the autonomous control board, when a circuit and an execution program constructed in the data processing FPGA device are debugged, the communication device can be attached (connected) to the debug connector.

(10) The autonomous control board according to any one of (1) to (9),

further comprising a power relay configured to conduct in response to an output signal of the external control FPGA device.

According to the above configuration, for example, the external control FPGA device can output a signal through the power relay. In addition, for example, when power is not supplied to the external control FPGA device, a signal can be outputted through the power relay because the power relay does not conduct.

The FPGA is a field programmable gate array.

The external control FPGA device is a semiconductor device. The external control FPGA device includes a semiconductor chip and a package of a semiconductor chip. The data processing FPGA device is a semiconductor device. The data processing FPGA device includes a semiconductor chip and a package of a semiconductor chip. Therefore, the external control FPGA device and the data processing FPGA device are semiconductor devices that are independent of each other.

The on-board controlled object may have its own controller. The on-board controlled object may be, for example, an actuator. The on-board controlled object may be, for example, a driver for supplying power to an actuator.

The term “electrically connected” means that being connected so that an electrical signal is transmitted. For example, being connected through passive elements such as resistors and inductors for transmitting signals, wiring, and sockets corresponds to being electrically connected. For example, being communicatively connected through wireless means being communicatively connected but not electrically connected.

The term “communicatively connected” means, for example, being electrically connected, but the term is not particularly limited, and includes, for example, a configuration that is communicable through wireless communication.

A processor provided in the external control FPGA device may output a part of the processing results of the received external environmental data to the data processing FPGA device. The processor provided in the external control FPGA device may also output all of the processing results of the external environment data to the data processing FPGA device. Processing of the external environment data includes, for example, processing for storing data in an external memory and processing for transferring data stored in the memory.

The term “a data processing line is independent of a command transmission pathway” means that a command transmission pathway does not include a data processing line. More specifically, when there is one or less portion where the data processing line is directly or indirectly connected to a component of the command transmission pathway, the data processing line is independent of the command transmission pathway. For example, when a part of the data processing line is connected to an external control FPGA device, which is a component of the command transmission pathway, and when the other part of the data processing line is not directly nor indirectly connected to any of the components of the command transmission pathway, the data processing line is independent of the command transmission pathway. On the other hand, when a part of the line is connected to the first component of the command transmission pathway and when the other part of the line is directly or indirectly connected to the second component of the command transmission pathway, the line is not independent of the command transmission pathway and is included in the command transmission pathway. This is because, in this case, the data is transmitted from the first component to the second component through the line, which substantially functions as a command transmission pathway. In other words, the line branching from the command transmission pathway and not returning to the command transmission pathway is independent of the command transmission pathway.

Here, being connected means being electrically connected so as to be able to transmit signals. For example, when the connection is made through an insulating member, or when the connection is made exclusively for power transmission, this case does not correspond to the connection described in this definition of independence.

One example of the external environment data obtainer is an external environment data obtaining connector. It is noted that the external environment data obtainer is not limited to this, and may be, for example, an external environment data signal receiving circuit or a wireless communication circuit.

One example of the external command data receiver is an external command data receiving connector. It is noted that the external command data receiver is not limited to this, and may be, for example, an external command data signal receiving circuit or a wireless communication circuit.

One example of the control signal outputter is a control signal outputting connector. It is noted that the control signal outputter is not limited to this, and may be, for example, a control signal transmission circuit or a wireless communication circuit.

The processor sequentially executes a program. The processor may have a plurality of processor cores for sequentially executing programs. In other words, a plurality of programs may be executed simultaneously in the processor.

The external environment sensor obtains external environment information of the autonomous functioning apparatus. The external environment information refers to information related to an external environment of the autonomous functioning apparatus. Herein, the external environment of the autonomous functioning apparatus includes at least a possible range on which the functioning of the autonomous functioning apparatus has an influence. This range is not limited to the range on which the functioning of the autonomous functioning apparatus can directly have an influence, but includes the range on which the functioning of the autonomous functioning apparatus can indirectly have an influence. Further, the change of the external environment of the autonomous functioning apparatus is not limited to the change of the external environment itself, but includes the change of the external environment generated by the functioning of the autonomous functioning apparatus in the relative relation with the autonomous functioning apparatus. In addition, the external environment can change over time. Therefore, the external environment sensor continuously obtains, as external environment information, at least information on a change within a possible range on which the functioning of the autonomous functioning apparatus has the influence. Thus, the external environment sensor can obtain information on a change over time within the range. The external environment sensor outputs the obtained external environment information as external environment data. The external environment data is, for example, continuously outputted from the external environment sensor. The external environment data is, for example, data relating to a possible range on which the functioning of the autonomous functioning apparatus has the influence. The external environment sensor is, for example, a camera for capturing an external image. The camera outputs image data representing an image. However, the external environment sensor is not particularly limited, and may be, for example, a LIDAR (Laser Imaging Detection and Ranging) sensor. The external environment sensor is not, for example, a single point measurement type. The external environment sensor may be, for example, a multi-point measurement type or an area measurement type. In the present teaching, an area measurement type external environment sensor can be preferably used. The camera or the LIDAR described above is an example of an area measurement type external environment sensor that continuously functions. Such an external environment sensor, for example, outputs many external environment data per sensor. Therefore, as the number of external environment sensors changes, the amount of data processed by the autonomous control board greatly changes. The autonomous control board can suitably respond to such a change in data amount, and great scalability can be achieved.

The autonomous functioning apparatus is, for example, an autonomous travelling vehicle. The autonomous functioning apparatus is not particularly limited, and may be, for example, an autonomous functioning robot. The autonomous functioning apparatus is configured, for example, so that the functioning of the autonomous functioning apparatus itself can cause a physical change to outside the autonomous functioning apparatus. The autonomous functioning apparatus itself may be configured, for example, to be movable as a whole. The autonomous functioning apparatus may be configured, for example, such that at least a part of the autonomous functioning apparatus is movable. The autonomous functioning apparatus may be configured, for example, to be partially fixed. An example of an autonomous functioning apparatus is a device for discharging or sucking powder or fluid. This is because, although the autonomous functioning apparatus itself does not cause physical changes to outside the autonomous functioning apparatus, either the discharged powder or fluid or the sucking of fluid or powder by such devices causes physical changes to outside the autonomous functioning apparatus. The fluid is liquid or gas. The powder is solid and has a property as fluid. A device that autonomously performs arithmetic processing and outputs the arithmetic result as data or a command does not cause physical change to outside the autonomous functioning apparatus. A device that causes a physical change only to inside the autonomous functioning apparatus does not cause a physical change to outside the autonomous functioning apparatus.

The command device is, for example, an external command device provided outside the autonomous functioning apparatus. However, the command device is not particularly limited, and may be, for example, on-board the autonomous functioning apparatus. The command device is different from the on-board controlled object that is on-board the autonomous functioning apparatus.

A command is not limited to one corresponding to the sequential functioning of the autonomous functioning apparatus. For example, when the autonomous functioning apparatus performs a series of functioning based on an external environment, and when the autonomous functioning apparatus commands an initiation of the series of functioning, the contents of the command are the initiation of the series of functioning. A series of functioning is a combination of a plurality of functioning performed simultaneously or sequentially after receiving a command. For example, when the driving functioning and the steering functioning are performed after receiving the command for driving without receiving any further command, the driving functioning and the steering functioning are a series of functioning. However, the command is not particularly limited, and may be, for example, a command corresponding to the sequential functioning of the autonomous functioning apparatus.

Instead of directly receiving the command data from the outside, the command data receiver may receive the command data through a receiver that is provided outside the autonomous control board and that directly receives the command data from the outside.

The command transmission pathway is a pathway for transmitting a control command from the external command data receiver to the control signal outputter. The content and amounts of the transmitted control command may vary depending on the processing in the middle. A plurality of devices connected to each other along a command transmission pathway outputs data to a downstream device in response to receiving data from an upstream device, in which the external command data receiver is in the uppermost stream. The flow of commands for outputting data in response to receiving data continues along the command transmission pathway to the control signal outputter. The content, amount, timing, and frequency of data received and transmitted by a single device may not be same, but may be different from each other. For example, in response to receiving data from the upstream device, the processed data with reference to the external data may be outputted to the downstream device.

On the other hand, when the data is outputted to the upstream device again without outputting the data to a device different from the upstream device in response to receiving the data from the upstream device, the device is not in the “command transmission pathway”. The device is connected to a data line independent of the command transmission pathway.

The data processing FPGA device inputs data to be processed from the external control FPGA device and outputs processed data to the external control FPGA device. On the other hand, the external control FPGA device inputs command data from the external command data receiver. The external control FPGA device outputs a functioning control signal to the control signal outputter. The external control FPGA device performs control due to command data, and outputs data to be processed to the data processing FPGA device.

The data processing FPGA device may not perform all processing based on command data or external environment data. For example, the external control FPGA device performs a part of processing based on the command data or the external environment data by itself, and outputs data necessary for the remaining processing to the data processing FPGA device as data to be processed. The external control FPGA device further processes the processed data outputted from the data processing FPGA device, and outputs a functioning control signal based on this result of the processing. In this manner, the external control FPGA device may share control processing with the data processing FPGA device. However, unlike the data processing FPGA device, since the external control FPGA device receives the command data more directly, the external control FPGA device outputs the data to be processed to the data processing FPGA device and receives the processed data from the data processing FPGA device.

As described above, the ratio of the sharing of processing between the external control FPGA device and the data processing FPGA device is not particularly limited, and can be set depending on the amount of available resources of each device. For example, the external control FPGA device may have the data processing FPGA device perform most of the processing of the substantial analysis of data, and may only classify, distribute, and integrate the command data, the external environment data, the functioning control signal, the data to be processed, and the processed data.

The printed wiring board is a printed circuit board on which components are mounted. The printed circuit board is, for example, a rigid board having a relatively small flexibility. The rigid board is, for example, a board made of a glass epoxy or a phenolic material. However, the printed circuit board may be a flexible board.

Circuits and components other than those described herein such as the external environment data obtainer, the control signal outputter, and the functioning control signal generation circuit may be mounted on the printed circuit board.

### Effect of the Invention

The present teaching can provide a highly scalable and highly versatile autonomous control board for use in an autonomous functioning apparatus.

### BRIEF DESCRIPTION OF THE DRAWINGS

FIG. 1 is a block diagram showing a configuration of an autonomous control board according to a first embodiment of the present teaching.

FIG. 2 is a block diagram showing a first example of the autonomous control board shown in FIG. 1.

FIG. 3 is a block diagram showing a first application of the autonomous control board shown in FIG. 2.

FIG. 4 is a block diagram showing a first application of the autonomous control board shown in FIG. 2.

FIG. 5 is a block diagram showing a conventional solution, in which a plurality of FPGA devices is employed in response to processing that cannot be performed by a single FPGA device.

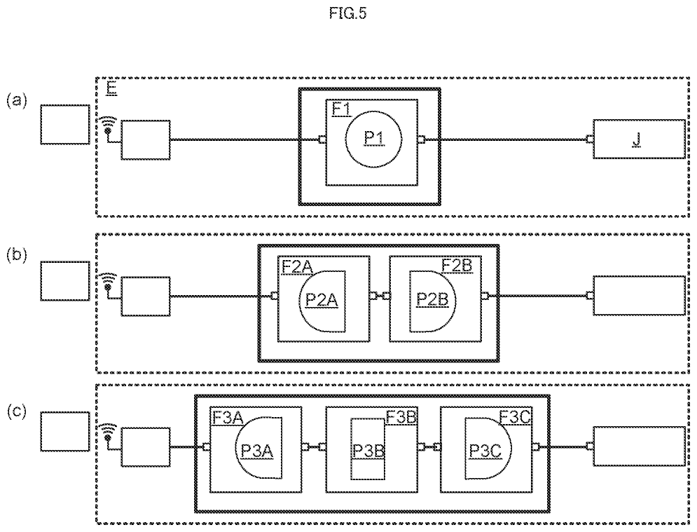

### DESCRIPTION OF EMBODIMENTS

Embodiments of the present teaching will be described below with reference to the drawings.

### First Embodiment

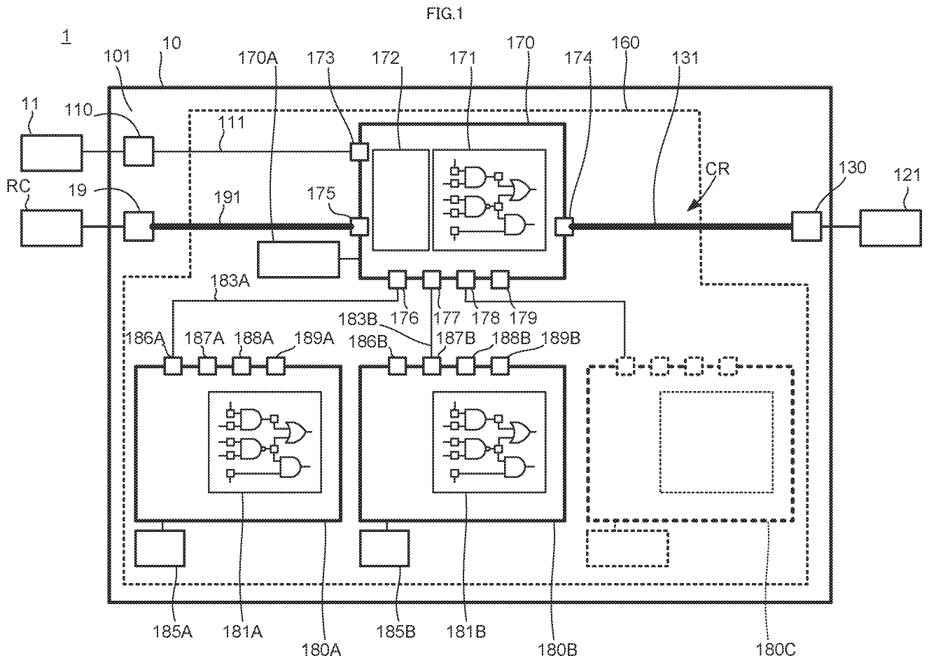

FIG. 1 is a block diagram showing a configuration of the autonomous control board according to the first embodiment of the present teaching.

The autonomous control board 10 shown in FIG. 1 is a board used for the autonomous functioning apparatus 1. The autonomous functioning apparatus 1 can autonomously perform a series of functioning without an operator, that is, the human operation. However, a series of functioning is at least initiated by an operation. The external command device RC is provided outside the autonomous functioning apparatus 1. The external command device RC commands at least an initiation of a series of functioning. For example, even when the functioning is performed without the operation at the reserved time, the reservation of the time and the corresponding functioning are instructed prior to the functioning. That is, a series of functioning including the count up to the reservation time is initiated by a preceding operation. However, when a series of functioning is initiated by an operation, the series of functioning is autonomously performed without any operations. The series of functioning may include a count of the time to the next functioning. That is, the series of functioning includes functioning that does not involve movement or deformation of the component. The series of functioning is highly abstract in that, for example, going around so as to cover a predetermined range while avoiding an obstacle based on an image captured by the on-board camera. However, the contents of the series of functioning are not limited to this, and may be, for example, more specific contents such as “stopping after moving 20 m forward”.

The autonomous control board 10 includes an external command data receiver 19, an external environment data obtainer 110, a control signal outputter 130, and a functioning control signal generation circuit 160. The autonomous control board 10 is a printed circuit board. The printed circuit board is a single printed wiring board 101 on which electronic components are mounted. The external environment data obtainer 110, the control signal outputter 130, and the functioning control signal generation circuit 160 are mounted on the printed wiring board 101.

The external command data receiver 19 obtains command data transmitted from the external command device RC. The external command data receiver 19 wirelessly communicates with, for example, the external command device RC at a remote area. However, it is also possible to adopt a configuration in which the external command data receiver 19 is wired to the external command device RC.

The external command data receiver 19 supplies command data to the external control FPGA device 170. Command data is a control command that is transmitted to the external control FPGA device 170.

The external environment data obtainer 110 is communicably connected to the external environment sensor 11. The external environment sensor 11 obtains external environment information of the autonomous functioning apparatus 1. The external environment data obtainer 110 obtains external environment data outputted from the external environment sensor 11.

The external environment sensor 11 is, for example, a camera for capturing outside the autonomous functioning apparatus 1. In this case, the external environment data is image data. The external environment data obtainer 110 is, for example, a connector connected to a cable extending from the external environment sensor 11.

The control signal outputter 130 is communicably connected to the on-board controlled object 121 provided in the autonomous functioning apparatus 1. The control signal outputter 130 outputs a functioning control signal for controlling the on-board controlled object 121 to the on-board controlled object 121.

The on-board controlled object 121 is, for example, a functioning device having an actuator and mechanically functioned by electric control. For example, when the autonomous functioning apparatus 1 is a vehicle, the on-board controlled object 121 is a travelling device having a motor as an actuator. The on-board controlled object 121 may include a control device different from the autonomous control board 10 for controlling, for example, an actuator. However, the on-board controlled object 121 is not limited to this, and may be, for example, an actuator without a control device.

The functioning control signal generation circuit 160 generates a functioning control signal based on command data. The functioning control signal generation circuit 160 generates a functioning control signal based on the external environment data. The functioning control signal generation circuit 160 starts the control of the autonomous functioning based on the command data and continues the control based on the external environment data. The functioning control signal generation circuit 160 includes the external control FPGA device 170 and data processing FPGA devices 180A, 180B. In the example shown in FIG. 1, a single external control FPGA device 170 and two data processing FPGA devices 180A, 180B are provided. The functioning control signal generation circuit 160 includes an external environment data line 111 and a functioning control signal line 131. The functioning control signal generation circuit 160 includes a first memory 170A that is nonvolatile and second memories 185A, 185B. The functioning control signal generation circuit 160 includes a command data line 191 and a functioning control signal line 131. The command data line 191 transmits command data from the external command data receiver 19 to the external control FPGA device 170. The functioning control signal line 131 transmits a functioning control signal from the external control FPGA device 170 to the control signal outputter 130. The functioning control signal generation circuit 160 includes an external environment data line 111.

The external control FPGA device 170 includes a first logic circuit 171, a processor 172, a command receiving terminal 175, a control outputting terminal 174, FPGA connection terminals 176, 177, 178, 179, and a data obtaining terminal 173. The first logic circuit 171 is a programmable circuit. That is, the first logic circuit 171 is a reprogrammable logic circuit. The external control FPGA device 170 loads connection information from the outside in initialization processing after power-on or reset, and constructs a processing function of the first logic circuit 171 based on this connection information. The external control FPGA device 170 starts processing after the processing function of the first logic circuit 171 has been constructed.

The processor 172 executes a program stored in the memory while sequentially reading the program by accessing the external memory after initialization processing after power-on or reset. On the other hand, in the first logic circuit 171, the processing function is basically constructed based on the connection information from the outside before the execution of the circuit, that is, at the time of initialization. In other words, the reading of the external memory is completed before the execution of the processing is started.

The external environment data line 111 transmits external environment data from the external environment data obtainer 110 to the external control FPGA device 170.

The functioning control signal line 131 transmits a functioning control signal from the external control FPGA device 170 to the control signal outputter 130.

The control outputting terminal 174 is connected to the control signal outputter 130 and outputs a functioning control signal for controlling the on-board controlled object 121.

The command receiving terminal 175 receives command data from the external command device RC provided outside the autonomous functioning apparatus 1. The command receiving terminal 175 is connected to the external command data receiver 19 through a command data line 191.

The data obtaining terminal 173 is connected to the external environment data line 111 and receives external environment data.

The FPGA connection terminals 176, 177, 178, and 179 are used for communicatively connecting the data processing FPGA devices 180A and 180B.

The autonomous control board 10 has a command transmission pathway CR. The command transmission pathway CR is configured to transmit a control command between the external command data receiver 19 and the control signal outputter 130. The autonomous control board 10 has the external command data receiver 19, the command data line 191, the external control FPGA device 170, the functioning control signal line 131, and the control signal outputter 130. The control command is either command data or a functioning control signal. The command transmission pathway CR includes the external command data receiver 19, the command data line 191, the external control FPGA device 170, the functioning control signal line 131, and the control signal outputter 130. The command transmission pathway CR transmits a control command from the external command data receiver to the control signal outputter.

More specifically, the external command data receiver 19, the command data line 191, the external control FPGA device 170, the functioning control signal line 131, and the control signal outputter 130 form the command transmission pathway CR.

The data processing FPGA device 180A includes a second logic circuit 181A. The other data processing FPGA device 180B also includes a second logic circuit 181B.

The plurality of data processing FPGA devices 180A and 180 B has one-to-one connection to any one of a plurality of FPGA connection terminals 176, 177, 178, 179 of the external control FPGA device 170. In the example shown in FIG. 1, the data processing FPGA device 180A has one-to-one connection to the FPGA connection terminal 176. The other data processing FPGA device 180B has one-to-one connection to the FPGA connection terminal 177. In the example of the autonomous control board 10 shown in FIG. 1, the remaining FPGA connection terminals 178 and 179 are spare terminals. The data processing FPGA devices 180A and 180B input data to be processed from the external control FPGA device 170 through data processing lines 183A, 183B, and output the processed data to the external control FPGA device 170.

The data processing FPGA device 180A includes FPGA connection terminals 186A, 187A, 188A, and 189A. The FPGA connection terminal 186A of the data processing FPGA device 180A is connected to the FPGA connection terminal 176 of the external control FPGA device 170.

The data processing FPGA device 180A is connected to the FPGA connection terminal 176 of the external control FPGA device 170 through the data processing line 183A.

The other data processing FPGA device 180B includes FPGA connection terminals 186B, 187B, 188B, and 189B. The FPGA connection terminal 187B of the data processing FPGA device 180B is connected to the FPGA connection terminal 177 of the external control FPGA device 170.

The data processing FPGA device 180B is connected to the FPGA connection terminal 177 of the external control FPGA device 170 through the data processing line 183B.

Each of the data processing lines 183A and 183B is a line independent of the command transmission pathway CR. The data processing lines 183A and 183B are not directly connected to any of the external command data receiver 19, the command data line 191, the functioning control signal line 131, or the control signal outputter 130. Therefore, none of the data processing FPGA devices 180A and 180B are directly connected to either the external command data receiver 19 or the control signal outputter 130.

None of the data processing FPGA devices 180A and 180B directly exchanges data with either the external command data receiver 19 or the control signal outputter 130. The data processing FPGA devices 180A and 180B indirectly exchange data with the external command data receiver 19 or the control signal outputter 130 through the external control FPGA device 170.

The external control FPGA device 170 in this embodiment mediates data in the command transmission pathway CR. More specifically, the command receiving terminal 175 of the external control FPGA device 170 receives command data from the external command device RC. The control outputting terminal 174 of the external control FPGA device 170 is connected to the control signal outputter 130 and outputs a functioning control signal for controlling the on-board controlled object 121. The command data or the functioning control signal is a functioning control command transmitted in the command transmission pathway CR.

The external control FPGA device 170 receives external environment data from the external environment data obtainer 110 through the external environment data line 111 connected to the data obtaining terminal 173. Each of two data processing FPGA devices 180A and 180B has respectively one-to-one connection to any one of the FPGA connection terminals 176, 177, 178, and 179 provided in the external control FPGA device 170. Consequently, the two data processing FPGA devices 180A and 180B can share at least a part of the processing based on the external environment data inputted to the external control FPGA device 170. Therefore, the autonomous control board 10 can control the on-board controlled object 121 provided in the autonomous functioning apparatus 1 based on the external environment data outputted from the external environment sensor 11 for obtaining the external information of the autonomous functioning apparatus 1.

As the autonomous functioning apparatus 1 become advanced, in the design stage of the autonomous control board 10, the command data received from the external command device RC may become more abstract than the actual condition of the previous model or the assumption in the design of the previous stage. For example, after command data including a destination in the autonomous travelling is received, the command may be executed while performing advanced processing such as travelling to the destination while regulating a travelling route in accordance with an image recognition result based on data of a camera as the external environment sensor 11. In such a case, one or more data processing FPGA devices 180A, 180B are not connected to the external command data receiver 19, and the external control FPGA device 170 is connected to the external command data receiver 19 and the control signal outputter 130. Accordingly, without changing the connection between the external command data receiver 19 and the control signal outputter 130, the increased processing can be responded by regulating the number of the data processing FPGA devices 180A and 180B connected to the plurality of FPGA connection terminals 176, and 177. In other words, the change for responding to the increased processing is possible while the basic configuration of the command transmission pathway CR for transmitting the functioning control command remain unchanged.

The processor 172 provided in the external control FPGA device 170 executes software. Accordingly, the external control FPGA device 170 can flexibly distribute processing to the data processing FPGA devices 180A and 180B depending on the increased or decreased amounts of external environment data outputted from the external environment sensor 11 in relation to the command data. Consequently, high scalability is achieved for various applications of the autonomous functioning apparatus 1.

As the autonomous functioning apparatus 1 become more advanced, some types of the autonomous functioning apparatus 1 may be provided with an external environment sensor 11 with different performance, and thus the amount of external environment data outputted from the external environment sensor 11 may be different from that of the conventional sensor. In such a case, one or more data processing FPGA devices 180A and 180B are not directly connected to the external environment data obtainer and the external control FPGA device 170 is connected to the external environment data obtainer 110. Accordingly, the different amounts of data can be processed without changing the connection to the external environment data obtainer 110 by regulating the number of data processing FPGA devices 180A and 180B, which process data. Since both the logic circuit of the external control FPGA device 170 and the data processing FPGA devices 180A and 180B are programmable, the logic circuit constructed in both FPGA devices 170, 180A, 180B can be easily changed when the application of the autonomous control board 10 is changed. In addition, for example, in response to the additional input of data other than the external environment data, the external control FPGA device 170 configured to execute software can flexibly distribute the processing and the data to the data processing FPGA devices 180A and 180B.

Consequently, high versatility is achieved for the types of the on-board controlled object in the autonomous functioning apparatus 1.

### First Application

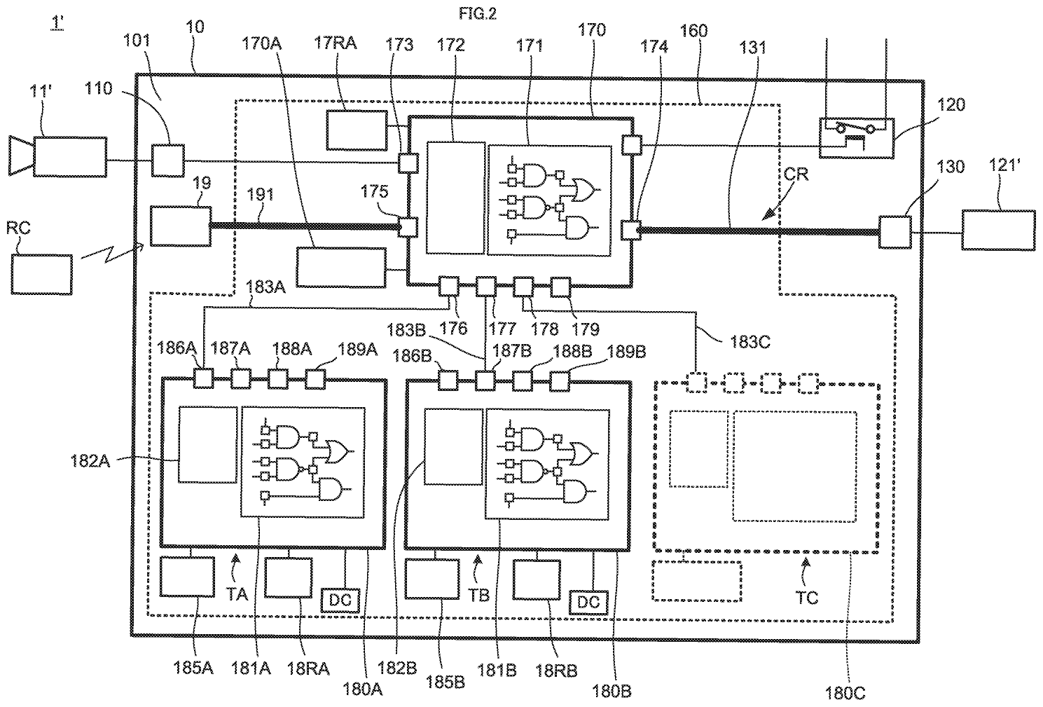

FIG. 2 is a block diagram showing a first example of the autonomous control board shown in FIG. 1.

In FIG. 2, elements corresponding to those in FIG. 1 are denoted by the same reference numerals as those in the first embodiment, and a part of the common description is omitted.

The autonomous control board 10 of the application shown in FIG. 2 is on-board the autonomous functioning apparatus 1′, which autonomously functions. The autonomous functioning apparatus 1′ detects the external environment of the autonomous functioning apparatus 1′ by itself. The autonomous functioning apparatus 1′ recognizes the content of the detected result and controls the functioning of the autonomous functioning apparatus 1′ based on the recognized result.

The autonomous functioning apparatus 1′ as an example on which the autonomous control board 10 is mounted is an autonomous travelling vehicle. A camera 11′ is used as the external environment sensor. A travelling device 121′ having an actuator is used as the on-board controlled object. That is, the autonomous functioning apparatus 1′ includes the camera 11′, the autonomous control board 10, and the travelling device 121′.

The external control FPGA device 170 obtains command data representing the initiation of a series of autonomous functioning from the external command device RC through the external command data receiver 19. The external control FPGA device 170 initiates the control of autonomous travelling based on the command data.

The autonomous functioning apparatus 1′ on which the autonomous control board 10 is mounted determines its own travelling route based on an image captured by the camera 11′ and travels. The autonomous control board 10 determines the travelling route of the autonomous functioning apparatus 1′ based on the image data of the image outputted from the camera 11′. The autonomous control board 10 controls the travelling device 121′ based on the determined travelling route. The travelling device 121′ travels the autonomous travelling vehicle as the autonomous functioning apparatus 1′ based on the control of the autonomous control board 10.

The autonomous control board 10 includes the external environment data obtainer 110, the control signal outputter 130, and the functioning control signal generation circuit 160.

The external environment data obtainer 110 is communicably connected to the camera 11′.

The camera 11′ captures the outside of the autonomous functioning apparatus 1′. The camera 11′ outputs image data representing the captured image as external environment data. The external environment data obtainer 110 is connected to, for example, a cable extending from the camera 11′. The external environment data obtainer 110 obtains image data outputted from the camera 11′.

The control signal outputter 130 is communicatively connected to the travelling device 121′. The control signal outputter 130 outputs a functioning control signal for controlling the travelling device 121′ to the travelling device 121′.

The travelling device 121′ is a functioning device having, for example, an actuator, and mechanically functioned by electrical control. The travelling device 121′ also includes a control device different from the autonomous control board 10, for example, for controlling an actuator.

The functioning control signal generation circuit 160 generates a functioning control signal based on image data. The functioning control signal generation circuit 160 includes the external control FPGA device 170 and two data processing FPGA devices 180A and 180B.

The external control FPGA device 170 includes the first logic circuit 171, the processor 172, the FPGA connection terminal 176, 177, 178, 179, and the data obtaining terminal 173. The first logic circuit 171 is a programmable circuit. That is, the first logic circuit 171 is a reprogrammable logic circuit. The external control FPGA device 170 loads connection information from the outside in initialization processing after power-on or reset, and constructs a processing function of the first logic circuit 171 based on the connection information. The external control FPGA device 170 starts processing after the processing function of the first logic circuit 171 is constructed.

The processor 172 executes the program stored in the memory while sequentially reading the program by accessing the external memory after initialization processing after power-on or reset. On the other hand, in the first logic circuit 171, the processing function is basically constructed based on the connection information from the outside before the execution of the circuit, that is, at the time of initialization. That is, the reading of the external memory is completed before the execution of the process is started.

The data obtaining terminal 173 is connected to the external environment data line 111 and receives image data.

The external environment data line 111 transmits image data from the external environment data obtainer 110 to an external control FPGA device 170.

The functioning control signal line 131 transmits a functioning control signal from the external control FPGA device 170 to the control signal outputter 130.

Each of the FPGA connection terminals 176, 177, 178, 179 is a dedicated terminal for communicating with an FPGA device other than the external control FPGA device 170. Each of the FPGA connection terminals 176, 177, 178, 179 is a high-speed transfer terminal having a maximum data transfer speed higher than the external environment data. The FPGA connection terminal 176, 177, 178, 179 is a terminal capable of performing serial communication.

A plurality of data processing device mount areas (or amounting areas) TA, TB, TC are formed on a single printed wiring board 101. Each of the data processing device mount areas TA, TB, TC is formed so as to be able to mount a data processing FPGA device. Each of the data processing device mount areas TA, TB, TC receives a plurality of data processing lines 183A, 183B, 183C extending from the external control FPGA device 170. That is, the plurality of data processing lines 183A, 183B, and 183C respectively extend from the external control FPGA device 170 to the data processing device mount areas TA, TB, and TC.

The data processing FPGA devices 180A and 180B are mounted on data processing device mount areas TA, TB, which are a part of data processing device mount areas TA, TB, TC.

The data processing FPGA device 180A includes a second logic circuit 181A and a processor 182A. The other data processing FPGA device 180B also includes a second logic circuit 181B and a processor 182B. A variety of processing that can be responded by the use of the data processing FPGA devices 180A and 180B can be wider by providing a processor in the data processing FPGA devices 180A and 180B.

The data processing FPGA device 180A has one-to-one connection to the FPGA connection terminal 176. The other data processing FPGA device 180B has one-to-one connection to the FPGA connection terminal 177. The FPGA connection terminals 178 and 179 are spare terminals.

The data processing FPGA device 180A includes the FPGA connection terminals 186A, 187A, 188A, 189A. The FPGA connection terminal 186A of the data processing FPGA device 180A and the FPGA connection terminal 176 of the external control FPGA device 170 are connected.

The other data processing FPGA device 180B includes FPGA connection terminals 186B, 187B, 188B, 189B. The FPGA connection terminal 187B of the data processing FPGA device 180B and the FPGA connection terminal 177 of the external control FPGA device 170 are connected.

The autonomous control board 10 includes the nonvolatile first memory 170A that is electrically connected to the external control FPGA device 170, and nonvolatile second memories 185A, 185B that are electrically connected to the data processing FPGA devices 180A, 180B. The autonomous control board 10 includes volatile memories 17RA, 18RA, 18RB that are electrically connected to the external control FPGA device 170 and the data processing FPGA devices 180A, 180B, respectively.

The first memory 170A stores configuration data of a logic circuit constructed in the external control FPGA device 170 (first configuration data). The second memories 185A and 185B store configuration data of a logic circuit constructed in the data processing FPGA devices 180A and 180B (second configuration data).

The first memory 170A has a capacity equal to or larger than any of the second memories 185A and 185B.

More specifically, the first memory 170A stores configuration data of a logic circuit secondarily constructed in the data processing FPGA devices 180A, 180B. The logic circuit constructed secondarily is different from the logic circuit constructed by the second configuration data of the second memories 185A, 185B. The logic circuit constructed secondarily is a circuit for processing image data in the data processing FPGA devices 180A and 180B.

In the second memories 185A and 185B, configuration data of an initialization circuit for constructing circuits of the data processing FPGA devices 180 A, 180 B by configuration data stored in the first memory 170A is stored.

The data processing FPGA devices 180A and 180B construct an initialization circuit by the second configuration data stored in the second memories 185A and 185B after resetting. The initialization circuit constructed in the data processing FPGA devices 180A and 180B reconstructs a logic circuit based on the first configuration data stored in the first memory 170A. In this case, the second memories 185A and 185B store only the second configuration data representing the initialization circuit regardless of the contents of the processing function of data. Since the first memory 170A has a capacity equal to or larger than any of the second memories 185A and 185B, configuration data of a circuit for processing image data reconstructed in the data processing FPGA devices 180A and 180B can be stored.

The autonomous control board 10 includes a debug connector DC connected to each of the data processing FPGA devices 180A and 180B. A communication device (not shown) that is communicable with the data processing FPGA devices 180A and 180B is removably connected to the debug connector DC. The communication device is, for example, a debugger device.

For example, during the maintenance of the autonomous control board 10, the communication device can be connected to the debug connector DC when debugging circuits and execution programs constructed in the data processing FPGA devices 180A and 180B.

The processing in the autonomous control board 10 of the example shown in FIG. 2 includes, for example, the following processing.

The external control FPGA device 170 obtains command data representing the initiation of a series of autonomous functioning from the external command device RC through the external command data receiver 19. The external control FPGA device 170 starts the control of autonomous travelling based on the command data. In control, the external control FPGA device 170 outputs a functioning control signal to the control signal outputter 130. In this way, the instruction from the external command device RC and the control of the on-board controlled object 121 are performed along the command transmission pathway CR from the external command data receiver 19 to the control signal outputter 130.

The external control FPGA device 170 receives image data outputted from the camera 11′. The external control FPGA device 170 outputs data based on the received image data to data processing FPGA devices 180A and 180B. The data that the external control FPGA device 170 outputs to the data processing FPGA devices 180A and 180B is, for example, image data. However, the data that the external control FPGA device 170 outputs may be, for example, data obtained by processing the image data.

The data processing FPGA devices 180A and 180B, for example, function as accelerators that assist the processing of image data received by the external control FPGA device 170. The data processing FPGA devices 180A and 180B share processing of image data. In the example shown in FIG. 2, the data processing FPGA devices 180A and 180B output the processed data to the external control FPGA device 170. The external control FPGA device 170 generates a functioning control signal based on the processed result outputted from the data processing FPGA devices 180A and 180B. The external control FPGA device 170 outputs a functioning control signal to the travelling device 121′. The data processing FPGA device 180A and the data processing FPGA device 180B perform different processing, for example, for common image data. However, the data processing FPGA device 180A and the data processing FPGA device 180B can be configured to process mutually different image data. For example, the data processing FPGA device 180A receives a part of the image data received by the external control FPGA device 170. The data processing FPGA device 180B receives a part of data different from a part of data received by the data processing FPGA device 180A.

Although the example of the processing has been described above, the processing in the autonomous control board 10 of the example shown in FIG. 2 is not limited to the above. For example, the external control FPGA device 170 can be configured to perform processing of image data, and the data processing FPGA devices 180A and 180B can be configured to perform processing other than image data processing. For example, the data processing FPGA devices 180A and 180B can be configured to perform processing of selecting a travelling route.

The autonomous control board 10 includes a power relay 120. The power relay 120 is connected to a power supply device (not shown) of the autonomous functioning apparatus 1′. The power relay 120 is controlled by the external control FPGA device 170. The power relay 120 is conducted by the output of the external control FPGA device 170. The power relay 120 controls the state of power supply to the autonomous functioning apparatus 1′ including the autonomous control board 10. For example, when the power relay 120 functions in response to the control of the external control FPGA device 170, the power supply to the power supply device (not shown) is cut off. The output signal of the power relay 120 can be connected in series with the power relay provided on a board (not shown) other than the autonomous control board 10. Thus, for example, when abnormal functioning of the autonomous control board 10 and the peripheral device is detected, the conduction of the autonomous functioning apparatus 1′ can be forcibly stopped. The forced stop can be achieved by a simple and highly reliable configuration using the power relay.

As the function of the vehicle as the autonomous functioning apparatus 1 become advanced, command data received from the external command device RC may be more abstract than the actual condition of the previous model or the assumption in the design of the previous stage. According to the autonomous control board 10 of this example, the data processing FPGA devices 180A, 180B, . . . are provided in a pathway independent of the command transmission pathway CR. Accordingly, as the application or function of the vehicle as the autonomous functioning apparatus 1 become advanced, the number of cameras 11′ or the processing of image data may be changed, and this change can be responded by regulating the number of the data processing FPGA devices 180A, 180B, . . . . For example, the data processing FPGA devices 180A, 180B, and 180C are mounted on all of the data processing device mount areas TA, TB, and TC, which are part of the data processing device mount areas TA, TB, and TC.

This case can be responded by regulating the number of data processing FPGA devices 180A, 180B, and 180C connected to the FPGA connection terminals 176, 177, 178, 179 without changing the connection with the external environment data obtainer 110. Therefore, it is possible to flexibly respond to the increased or decreased amounts of image data outputted from the camera 11′ that can be used for the autonomous functioning apparatus 1.

For example, in response to the additional input of data other than the external environment data, the external control FPGA device 170 configured to execute software can flexibly distribute the processing and the data to the data processing FPGA devices 180A, 180B, and 180C. Consequently, high versatility is achieved for the types of the on-board controlled object in the autonomous functioning apparatus 1.

Thus, the autonomous control board 10 can have high scalability and high versatility.

Each of the data processing FPGA devices 180A and 180B has one-to-one connection to the FPGA connection terminal 176 and 177 without having connection to the external environment data obtainer 110. Therefore, the processing capability of the autonomous control board 10 can be changed while a circuit for supplying image data to the external control FPGA device 170 remains unchanged. Therefore, the autonomous control board 10 has higher scalability.

The first memory 170A has a capacity equal to or larger than any of the second memories 185A and 185B. Therefore, the first memory 170A can store configuration data of the processing function of data, which is reconstructed in the data processing FPGA devices 180A and 180B. On the other hand, the second memories 185A and 185B can store configuration data of the initialization circuit constructed in the data processing FPGA devices 180 A, 180 B (second configuration data) regardless of the processing contents of image data. Accordingly, it is easy to add a data processing FPGA device including the second memory (e.g., 180C). Therefore, the autonomous control board 10 can have higher scalability and versatility.

Each of the FPGA connection terminals 176, 177, 178, 179 has a maximum data transfer speed higher than the external environment data. Consequently, each of the data processing FPGA devices 180A, 180B is allowed to perform processing for generating a functioning control signal after image data is transmitted to each of the data processing FPGA devices 180A, 180B.

The FPGA connection terminals 176, 177, 178, 179 performs serial communication. The number of the respective FPGA connection terminals 176, 177, 178, 179 is smaller than, for example, that of the parallel communication. Thus, more data processing FPGA devices 180A, 180B, 180C . . . can be connected to the external control FPGA device 170 having a limited number of terminals. Higher scalability can be achieved.

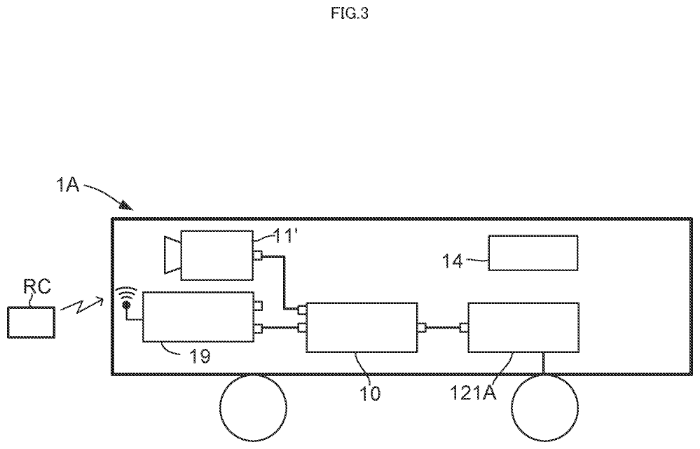

FIG. 3 is a block diagram showing a first application of the autonomous control board shown in FIG. 2.

The application shown in FIG. 3 is an autonomous travelling vehicle 1A. The autonomous travelling vehicle 1A includes the camera 11′, the autonomous control board 10, the travelling device 121A, the external command data receiver 19, and a power supply unit 14. The travelling device 121A is a device for travelling the autonomous travelling vehicle 1A. The external command data receiver 19 communicates with the external command device RC at a remote area.

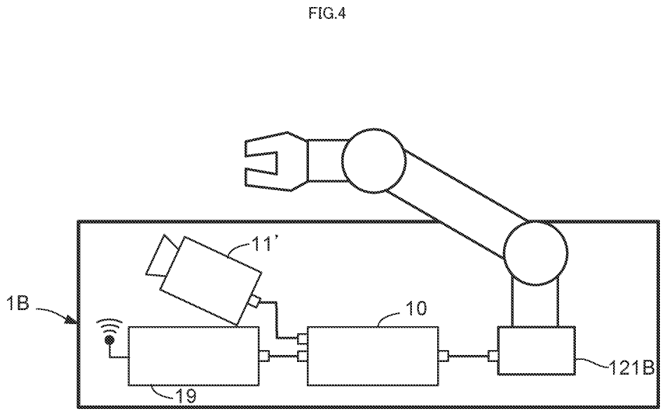

FIG. 4 is a block diagram showing a second application of the autonomous control board shown in FIG. 2.

The application shown in FIG. 4 is a robot arm 1B. The robot arm 1B includes the camera 11′, the autonomous control board 10, and an arm functioning device 121B.

The autonomous control board 10 shown in FIG. 2 is applicable to the autonomous travelling vehicle 1A or the robot arm 1B while changing, for example, the number of the data processing FPGA devices 180A, 180B, 180C . . . and the contents of the first configuration data without changing the basic structure of the autonomous control board 10.

### REFERENCE SIGNS LIST

1,1′ autonomous functioning apparatus

10 autonomous control board

11 external environment sensor

101 printed wiring board

110 external environment data obtainer

111 external environment data line

120 power relay

121 on-board controlled object

130 control signal outputter

131 functioning control signal line

160 functioning control signal generation circuit

170 external control FPGA device

171 first logic circuit

172 processor

173 data obtaining terminal

174 control outputting terminal

175 command receiving terminal

170A first memory

176,177,178,179 FPGA connection terminal

180A,180B data processing FPGA device

181A,181B second logic circuit

182A,182B processor

19 external command data receiver

DC debug connector

RC external command device

TA,TB,TC data processing device mount area

1. An autonomous control board for an autonomous functioning apparatus, the autonomous functioning apparatus autonomously performing a series of operations based on command data transmitted from a command device that is either on-board or off-board with respect to the autonomous functioning apparatus, the autonomous functioning apparatus including
an external environment sensor obtaining information of external environment of the autonomous functioning apparatus, and
an on-board controlled object that is disposed outside the autonomous control board and is different from the command device, the autonomous control board comprising:
an external command data receiver configured to obtain the command data transmitted from the command device for commanding at least an initiation of the series of operations;
an external environment data obtainer communicatively connected to the external environment sensor, and being configured to obtain external environment data outputted from the external environment sensor;
a control signal outputter communicatively connected to the on-board controlled object, and being configured to send a functioning control signal to the on-board controlled object, to thereby control the on-board controlled object; and
a functioning control signal generation circuit configured to generate the functioning control signal based on the command data, the functioning control signal generation circuit comprising:
an external control field-programmable gate array (FPGA) device including
a first logic circuit that is programmable, and
a processor;
at least one data processing FPGA device, each including a second logic circuit that is programmable;
a command data line configured to transmit the command data from the external command data receiver to the external control FPGA device; and
a functioning control signal line configured to transmit the functioning control signal from the external control FPGA device to the control signal outputter, wherein
the external control FPGA device further includes
a command receiving terminal connected to the external command data receiver through the command data line, the command receiving terminal being configured to receive the command data from the command device when the command device is off-board with respect to the autonomous functioning apparatus,
a control outputting terminal connected to the control signal outputter, the control outputting terminal being configured to output the functioning control signal for controlling the on-board controlled object, and
at least one FPGA connection terminal that is communicatively connected to the at least one data processing FPGA device; wherein
the external command data receiver, the command data line, the external control FPGA device, the functioning control signal line, and the control signal outputter form a command transmission pathway for transmitting a control command between the external command data receiver and the control signal outputter, the control command being either the command data or the functioning control signal, and
each of the at least one data processing FPGA device is one-to-one connected to one of the at least one FPGA connection terminals through a data processing line that is independent of the command transmission pathway, to thereby receive data that is to be processed from the external control FPGA device, and to thereby output processed data to the external control FPGA device.

2. The autonomous control board according to the claim 1, wherein
the external environment sensor is a camera that captures the external environment of the autonomous functioning apparatus, and
the external environment data obtainer obtains the image data, as the external environment data, outputted from the camera.

3. The autonomous control board according to claim 1, wherein
the autonomous control board is constituted of a single printed wiring board on which the command data line and the functioning control signal line are formed, and
the external control FPGA device, the at least one data processing FPGA device, the external command data receiver, and the control signal outputter are mounted on the single printed wiring board.

4. The autonomous control board according to the claim 3, wherein
the single printed wiring board has a plurality of data processing device mounting areas that receive a plurality of data processing lines extending from the external control FPGA device and on each of which one of the at least one data processing FPGA device is mountable,
the at least one data processing FPGA device is mounted on a part of or all of the plurality of data processing device mounting areas.

5. The autonomous control board according to claim 1, further comprising:
a non-volatile first memory configured to store first configuration data that represent a first circuit constructed by the first logic circuit of the external control FPGA device, the non-volatile first memory being electrically connected to the external control FPGA device; and
a non-volatile second memory configured to store second configuration data that represent at least a part of a second circuit constructed by the second logic circuit of one of the at least one data processing FPGA device, the non-volatile second memory being electrically connected to said one of the at least one data processing FPGA device, wherein
the non-volatile first memory has a capacity equal to or larger than that of the non-volatile second memory.

6. The autonomous control board according to claim 1, wherein
each of the at least one FPGA connection terminal of the external control FPGA device has a maximum data transfer speed higher than a maximum data transfer speed of the external environment data.

7. The autonomous control board according to claim 1, wherein
the processor of the external control FPGA device is a first processor, and
each of the at least one data processing FPGA device has a second processor.

8. The autonomous control board according to claim 1, wherein
each of the at least one FPGA connection terminal performs serial communication.

9. The autonomous control board according to claim 1, further comprising a debug connector connected to each of the at least one data processing FPGA device, the debug connector being removably connectable to a communication device that is communicable with said each of the at least one data processing FPGA device.

10. The autonomous control board according to claim 1, further comprising a power relay configured to be conductive in response to an output signal of the external control FPGA device.
